(19) United States
(12) Patent Application Publication
(10) Pub. No.: US 2025/0254973 A1
(43) Pub. Date: Aug. 7, 2025

(54) CONTACT INTEGRATION IN COMPLEMENTARY FIELD EFFECT TRANSISTOR (CFET) DEVICES

(71) Applicant: Applied Materials, Inc., Santa Clara, CA (US)

(72) Inventors: San-Kuei LIN, Cupertino, CA (US); Pradeep K. SUBRAHMANYAN, Santa Clara, CA (US)

(21) Appl. No.: 18/651,372

(22) Filed: Apr. 30, 2024

Related U.S. Application Data
(60) Provisional application No. 63/549,299, filed on Feb. 2, 2024.

(51) Int. Cl. H01L 21/8238; H01L 21/28; H01L 21/285; H01L 21/822; H01L 23/528; H01L 27/092; H01L 29/06; H01L 29/08; H01L 29/417; H01L 29/423; H01L 29/66; H01L 29/775

(52) U.S. Cl. CPC H10D 84/038; H01L 21/28123; H01L 21/28518; H01L 23/5286; H10D 30/014; H10D 30/43; H10D 30/6729; H10D 30/6735; H10D 62/121; H10D 62/151; H10D 84/0186; H10D 84/0188; H10D 84/856; H10D 88/01

(57) ABSTRACT

A semiconductor structure includes a bottom field effect transistor (FET) module, the bottom FET module including a bottom metal gate, a pair of bottom source/drain (S/D) contacts, and a top FET module on the bottom FET module in a second direction that is orthogonal to the first direction, the top FET module including a top metal gate, a pair of top S/D contacts, and a top-to-bottom interconnect extending through the bottom FET module and the top FET module in the second direction, a bottom liner covering surfaces of the top-to-bottom interconnect along a plane parallel to the first direction and the second direction, and a top liner covering surfaces of the top-to-bottom interconnect along a plane orthogonal to the first direction.

### CROSS-REFERENCE TO RELATED APPLICATIONS

This application claims priority to U.S. Provisional Application Ser. No. 63/549,299 filed Feb. 2, 2024, which is herein incorporated by reference in its entirety.

### BACKGROUND

### Field

Embodiments described herein generally relate to semiconductor device fabrication, and more particularly, to contact integration in complementary field effect transistor (CFET) devices.

### Description of the Related Art

To continue scaling beyond the physical limit of planar metal oxide semiconductor field effect transistor (MOSFET), three-dimensional FinFET, stacked nanosheet gate-all-around FET (GAA FETs), and complementary FET (CFET) have been proposed. In a CFET architecture, n- and p-devices are stacked on top of each other vertically, and a power distribution network is designed to be implemented at the bottom of the device, which helps in optimizing routing of interconnect.

Improvement in a CFET architecture further reducing device footprint and total interconnect metal length to reduce parasitic resistance is needed.

### SUMMARY

Embodiments of the present disclosure provide a semiconductor structure. The semiconductor structure includes a bottom field effect transistor (FET) module, the bottom FET module including a bottom metal gate, a pair of bottom source/drain (S/D) contacts electrically connected to each other through the bottom metal gate in a first direction via bottom S/D epitaxial (epi) regions, and a top FET module stacked on the bottom FET module in a second direction that is orthogonal to the first direction, the top FET module including a top metal gate, a pair of top S/D contacts electrically connected to each other through the top metal gate via top S/D epi regions, and a top-to-bottom interconnect extending through the bottom FET module and the top FET module in the second direction, a bottom liner covering surfaces of the top-to-bottom interconnect along a plane parallel to the first direction and the second direction, and a top liner covering surfaces of the top-to-bottom interconnect along a plane orthogonal to the first direction.

Embodiments of the present disclosure provide a method of forming a complementary field-effect transistor (CFET). The method includes exposing a top metal gate, wherein: the top metal gate is stacked on a bottom metal gate in a first direction, and the top metal gate and the bottom metal gate are embedded within in an inter-layer dielectric (ILD) and extend along a plane parallel to the first direction and a second direction orthogonal to the first direction, cutting the top metal gate and the bottom metal gate using a metal gate cut hardmask deposited over the top metal gate and the ILD, and form cavities through the top metal gate, the bottom metal gate, and the ILD, depositing a bottom liner on exposed inner surfaces of the cavities and on the metal gate cut hardmask, filling the cavities with cut metal gate (CMG) isolation gap-fill material, removing the metal gate cut hardmask and overfilled portions of the bottom liner and the CMG isolation gap-fill material over the top metal gate, forming a top contact trench extending along the plane parallel to the first direction and the second direction, using a top contact etch hardmask, and expose a pair of top source/drain (S/D) contacts that are electrically connected to each other through the top metal gate, depositing a top liner on exposed inner surfaces of the top contact trench, removing the top liner from a bottom of the top contact trench and from the top contact etch hardmask, forming metal silicide on exposed surfaces of the top S/D contacts, depositing a carbon bottom layer within the top contact trench and over the top contact etch hardmask, forming a via through the carbon bottom layer, forming a bottom via through the ILD using the patterned carbon bottom layer, removing the carbon bottom layer, filling the bottom via and the top contact trench with contact metal fill material, and removing the top contact etch hardmask and form a contact plug and a top-to-bottom interconnect.

Embodiments of the present disclosure provide a method of forming a complementary field-effect transistor (CFET). The method includes cutting a top metal gate and a bottom metal gate embedded in an inter-layer dielectric (ILD) using a metal gate cut hardmask deposited over the top metal gate and the ILD, and form cavities through the top metal gate, the bottom metal gate, and the ILD, wherein: the top metal gate is stacked on the bottom metal gate in a first direction, the top metal gate and the bottom metal gate extend along a plane parallel to the first direction and a second direction orthogonal to the first direction, and the cavities extend along a plane orthogonal to the second direction, depositing a bottom liner on exposed inner surfaces of the cavities and on the metal gate cut hardmask, filling the cavities with cut metal gate (CMG) isolation gap-fill material, removing the metal gate cut hardmask and overfilled portions of the bottom liner and the CMG isolation gap-fill material over the top metal gate, forming a top contact trench extending along the plane parallel to the first direction and the second direction, using a top contact etch hardmask, and expose a pair of top source/drain (S/D) contacts that are electrically connected to each other through the top metal gate, depositing a top liner on exposed inner surfaces of the top contact trench, removing the top liner from a bottom of the top contact trench and from the top contact etch hardmask, forming metal silicide on exposed surfaces of the top S/D contacts, depositing a carbon bottom layer within the top contact trench and over the top contact etch hardmask, forming a via through the carbon bottom layer, forming a bottom via through the ILD using the patterned carbon bottom layer, removing the carbon bottom layer, and filling the bottom via and the top contact trench with contact metal fill material.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of the scope of the disclosure, as the disclosure may admit to other equally effective embodiments.

FIG. 1 is a schematic top view of a multi-chamber processing system, according to one or more embodiments of the present disclosure.

FIG. 2 is an isometric view of a portion of a semiconductor structure that may form a complementary field-effect transistor (CFET), according to one or more embodiments of the present disclosure.

FIGS. 3A and 3B depict a process flow diagram of a method of forming cell transistors in a semiconductor structure according to one embodiment.

FIGS. 4A, 4B, 4C, 4D, 4E, 4F, 4G, 4H, 4I, 4J, 4K, 4L, 4M, 4N, and 40 are isometric views of a portion of a semiconductor structure corresponding to various states of the method of FIGS. 3A and 3B.

To facilitate understanding, identical reference numerals have been used, where possible, to designate identical elements that are common to the figures. It is contemplated that elements and features of one embodiment may be beneficially incorporated in other embodiments without further recitation. In the figures and the following description, an orthogonal coordinate system including an X-axis, a Y-axis, and a Z-axis is used. The directions represented by the arrows in the drawings are assumed to be positive directions for convenience. It is contemplated that elements disclosed in some embodiments may be beneficially utilized on other implementations without specific recitation.

### DETAILED DESCRIPTION

The embodiments described herein provide a process integration method that optimizes metal routing in a complementary FET (CFET) device that includes a stack of an n-type FET device and a p-type FET device. According to the embodiments described herein, a power distribution network is designed to be implemented at the bottom of the device, which helps in optimizing the routing of metal interconnects. Routing and pitch of metal contacts in the top device can be relaxed, allowing for more flexibility in designing the device layout. The intra-cell routing (metal interconnect within a standard cell of transistors) can be moved to the source/drain level, which helps in reducing the complexity of metal routing in the top device. Thus, pitch of MO level metal layer can be relaxed and total metal routing distance can be reduced, leading to area reduction.

In the embodiments described herein, integration of metal contacts is optimized by using a dual damascene integration technique, including a trench/via structure for contact formation on the top device. The backside of the device utilizes trench contact integration, which further enhances the efficiency of the metal routing. The process integration method further includes self-alignment of a top-to-bottom interconnect.

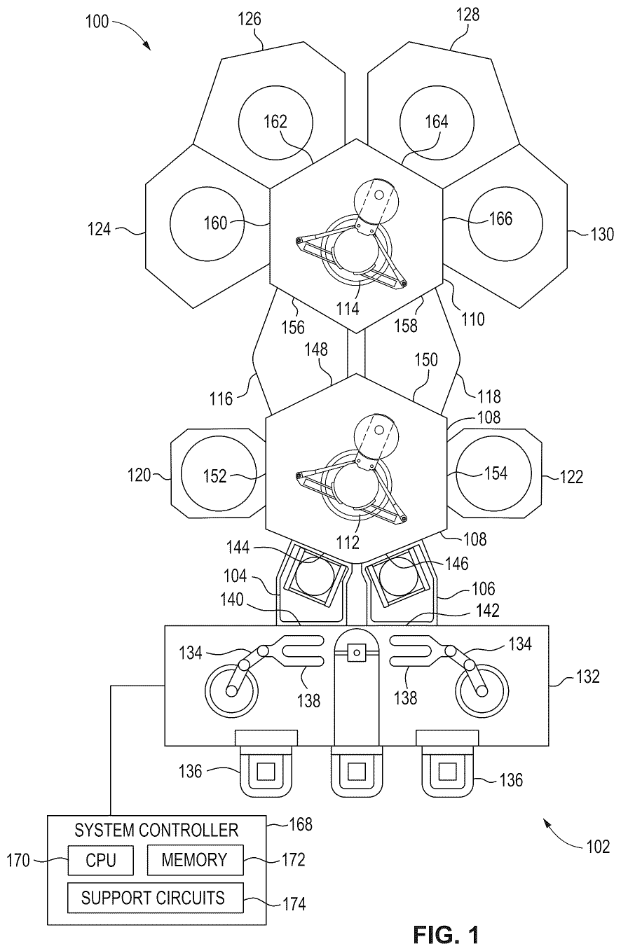

FIG. 1 is a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing etch processes, the processing chamber 122 can be capable of performing cleaning processes, the processing chamber 124 can be capable of performing selective removal processes, the processing chamber 126 can be capable of performing chemical vapor deposition (CVD) deposition processes, and the processing chambers 128, 130 can be capable of performing respective epitaxial growth processes.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

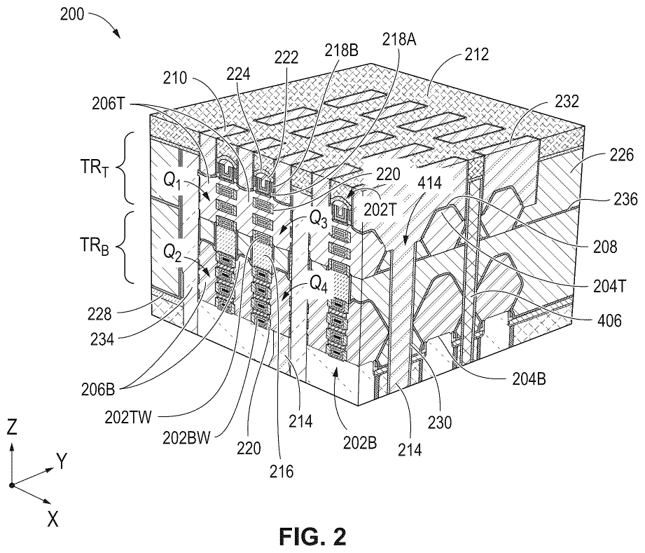

FIG. 2 is an isometric view of a portion of a semiconductor structure 200 that may form a complementary field-effect transistor (CFET), according to one or more embodiments of the present disclosure.

The semiconductor structure 200 shown in FIG. 2 includes a bottom field effect transistor (FET) module TRB, and a top FET module TRT stacked on the bottom FET module TRB in the Z direction. In one example, the bottom FET module TRB includes p-channel transistors Q2 and Q4, and the top FET module TRT includes n-channel transistors Q1 and Q3. Each of the p-channel transistors Q2 and Q4 is formed of a bottom metal gate 202B, a pair of bottom source/drain (S/D) contacts 204B each electrically connected to one end of channel layers (not shown) extending through the bottom metal gate 202B in the X direction via a bottom S/D epitaxial (epi) region 206B. Each of the n-channel transistor Q1 and Q3 is formed of a metal gate 202T, a pair of top S/D contacts 204T each electrically connected to one end of channel layers (not shown) extending through the top metal gate 202T in the X direction via a top S/D epi region 206T. The top S/D contacts 204T may be interfaced with a metal silicide 208 to lower the contact resistance. The n-channel transistor Q1 and Q3 in the top FET module TRT may be electrically connected to input terminals (not shown) via contact plugs 210 embedded within a top contact etch hardmask 212. The p-channel transistor Q4 in the bottom FET module TRB may be electrically connected to a power supply voltage (not shown) via a top-to-bottom interconnect 214. The top-to-bottom interconnect 214 extends through the bottom FET module TRB and the top FET module TRT in the Z direction.

The bottom metal gates 202B and the top metal gates 202T may be formed of tungsten (W), ruthenium (Ru), molybdenum (Mo), copper (Cu), cobalt (Co), titanium (Ti), nickel (Ni), silver (Ag), gold (Au), iridium (Ir), tantalum (Ta), platinum (Pt), conductive oxides or nitrides thereof, or any combination thereof. The bottom metal gates 202B and the top metal gates 202T may have different work function metals 202BW and 202TW thereon to match the electrical characteristics of the bottom FET module TRB and the top FET module TRT. The bottom metal gates 202B are electrically isolated from the top metal gates 202T by middle dielectric isolation (MDI) 216. Surfaces of the bottom metal gates 202B and the top metal gates 202T along the ZX plane are covered by gate spacers 218A and 218B and inner spacers 220 formed of dielectric material, such as silicon oxycarbide (SiOₓC_{y}), silicon carbon nitride (SiCN), silicon carbon oxynitride (SiCON), and silicon nitride (Si₃N₄). Surfaces of the top metal gates 202T along the XY plane are covered by a metal gate cap layer 222 and a metal gate liner 224.

The bottom S/D epi regions 206B in the bottom FET module TRB may be formed of epitaxially grown silicon germanium (SiGe), doped with p-type dopants such as boron (B) or gallium (Ga), with a concentration of between about 10²⁰ cm⁻³ and 5×·10²¹ cm⁻³, depending upon the desired conductive characteristic of the bottom S/D epi regions 206B. The top S/D epi regions 206T in the top FET module TRT may be formed of epitaxially grown silicon (Si), doped with n-type dopants, such as phosphorus (P), arsenic (As), or antimony (Sb), with a concentration of between about 10²⁰ cm⁻³ and 5×10²¹ cm⁻³, depending upon the desired conductive characteristic of the top S/D epi regions 206T. In some other embodiments, the bottom S/D epi regions 206B in the bottom FET module TRB may be doped with n-type dopants, and the top S/D epi regions 206T in the top FET module TRT may be doped with p-type dopants.

The bottom S/D epi regions 206B and the top S/D epi regions 206T are embedded within an inter-layer dielectric (ILD) 226 formed of silicon oxide (SiO₂), silicon oxynitride (SiON), aluminum oxide (Al₂O₃), or any combination thereof. The ILD 226 is protected by shallow trench isolations (STIs) 228. The STIs 228 may be formed of silicon oxide (SiO₂).

The contact plugs 210 and the top-to-bottom interconnects 214 are formed of tungsten (W), cobalt (Co), molybdenum (Mo), ruthenium (Ru), or any low resistance metals. Surfaces of the top-to-bottom interconnect 214 along the ZX plane are covered by a bottom liner 230. Surfaces of the top-to-bottom interconnect 214 along the YZ plane is covered by a top liner 232. The bottom liner 230 and the top liner 232 may be formed of silicon nitride (Si₃N₄), silicon carbon nitride (SiCN), or silicon carbon oxynitride (SiCON), having a thickness of between about 0.5 nm and about 3 nm.

The semiconductor structure 200 further includes single diffusion breaks (SDBs) 234 to isolate adjacent transistors, and a contact etch stop layer (CESL) 236.

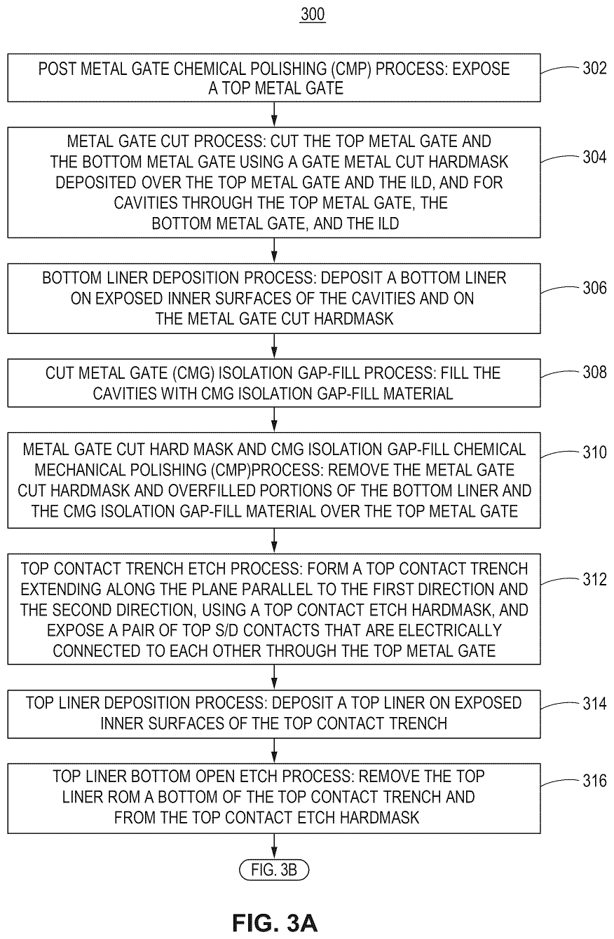

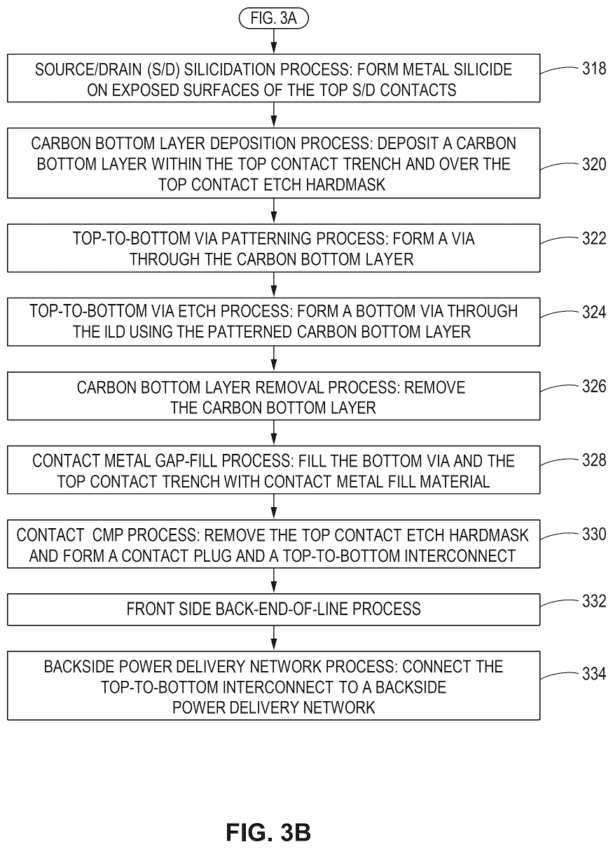

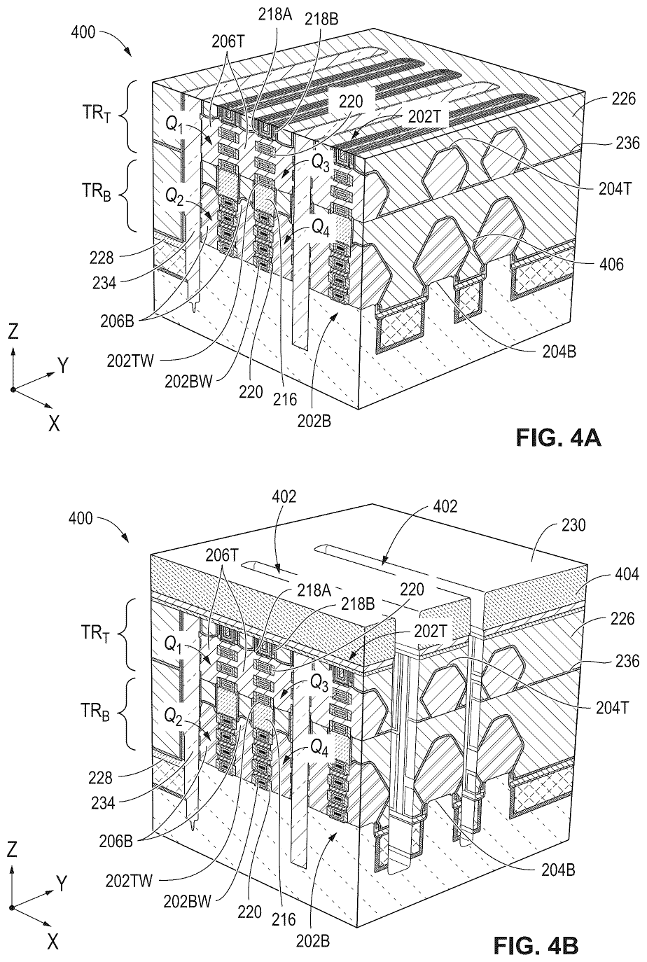

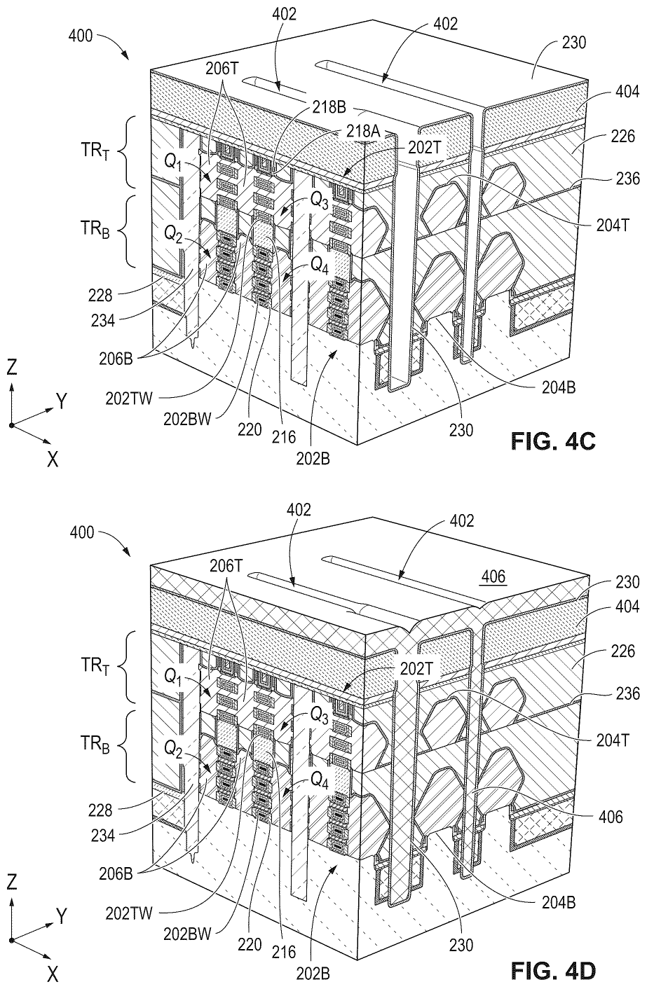

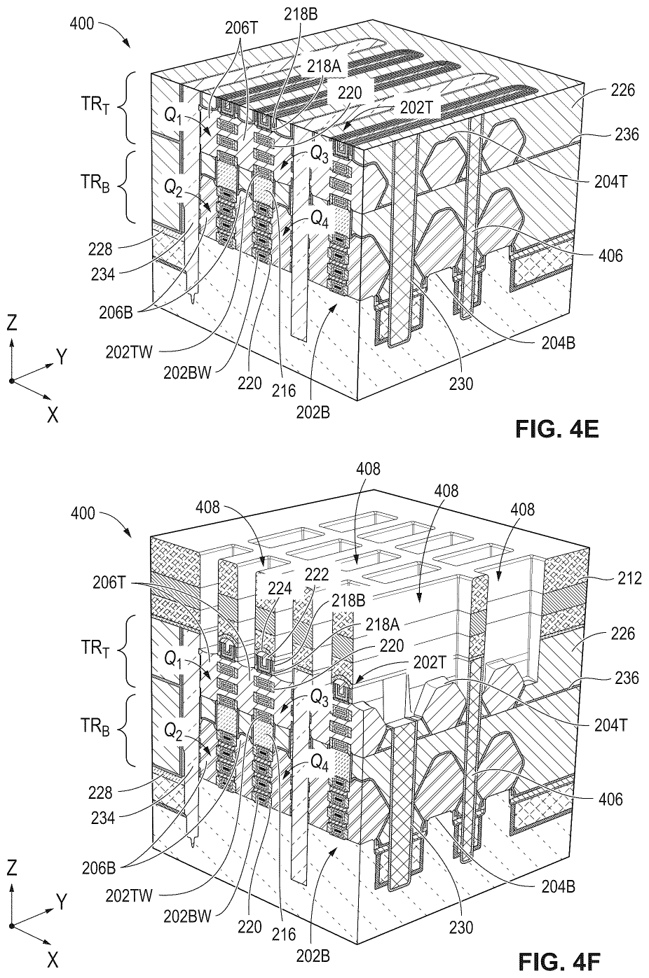

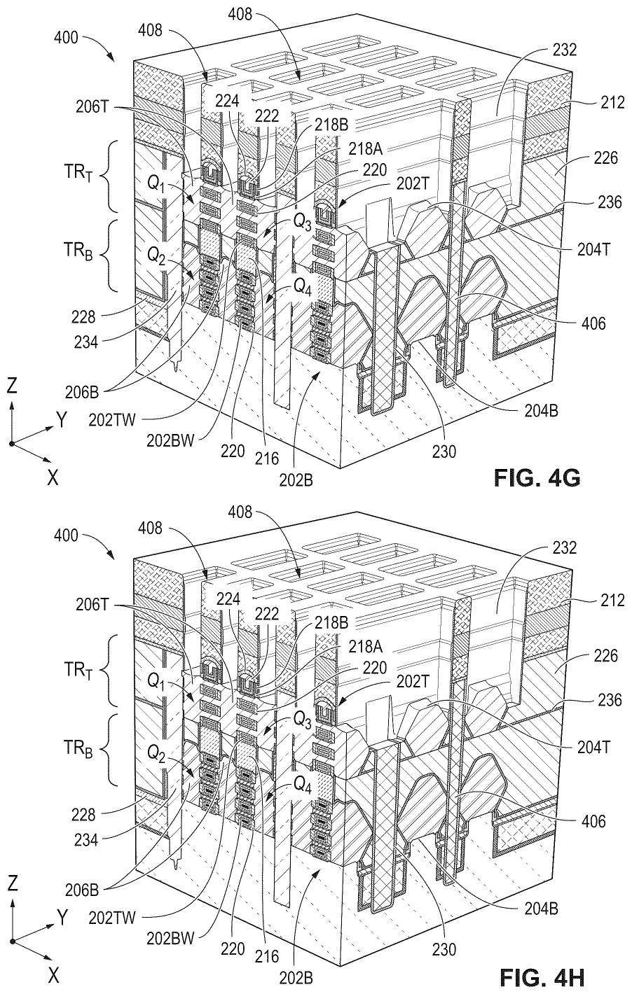

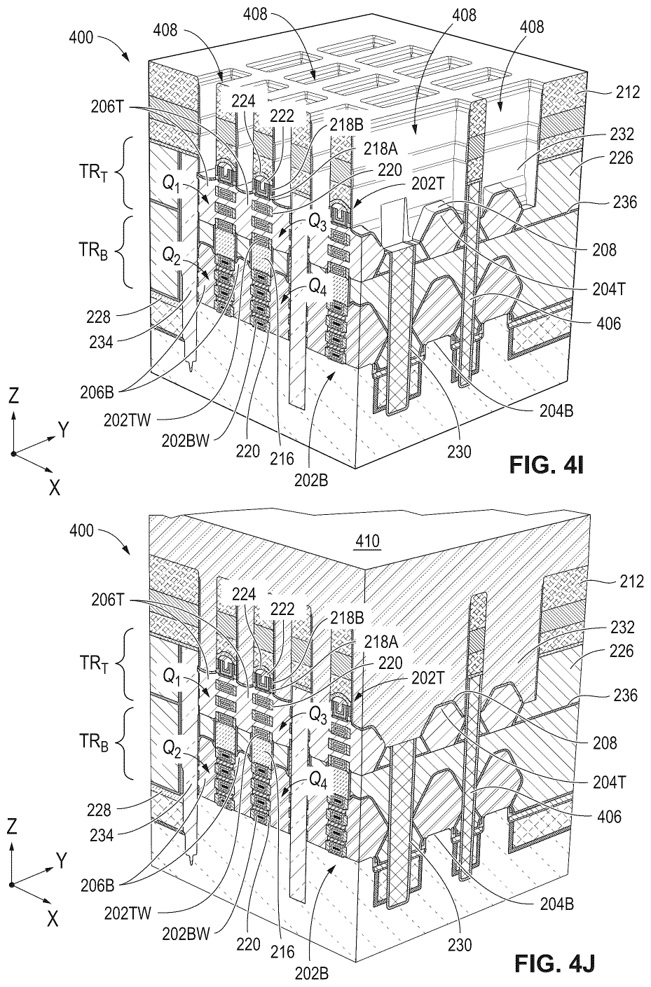

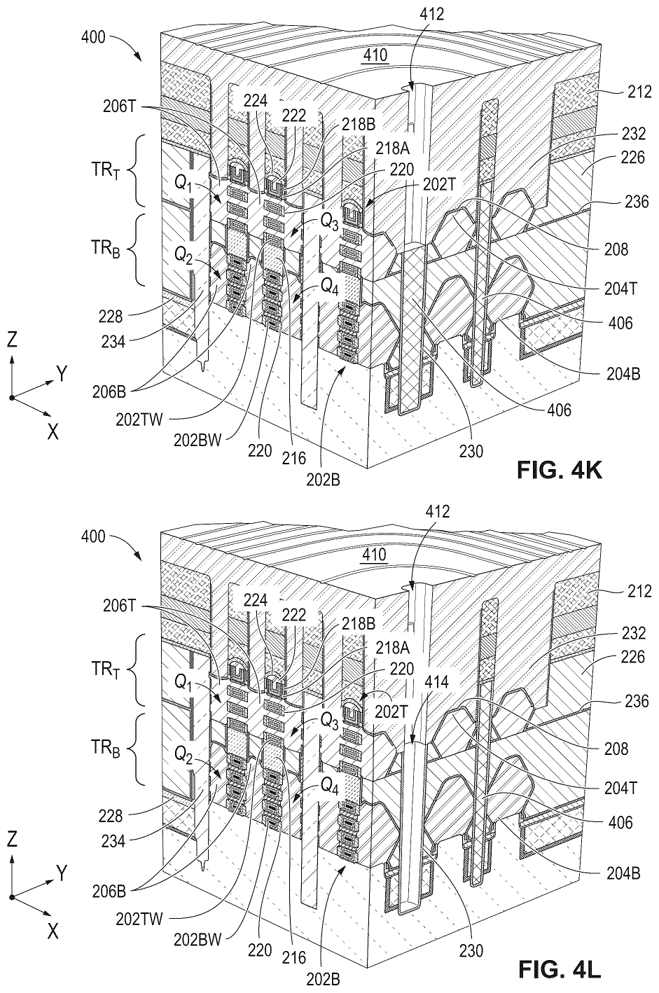

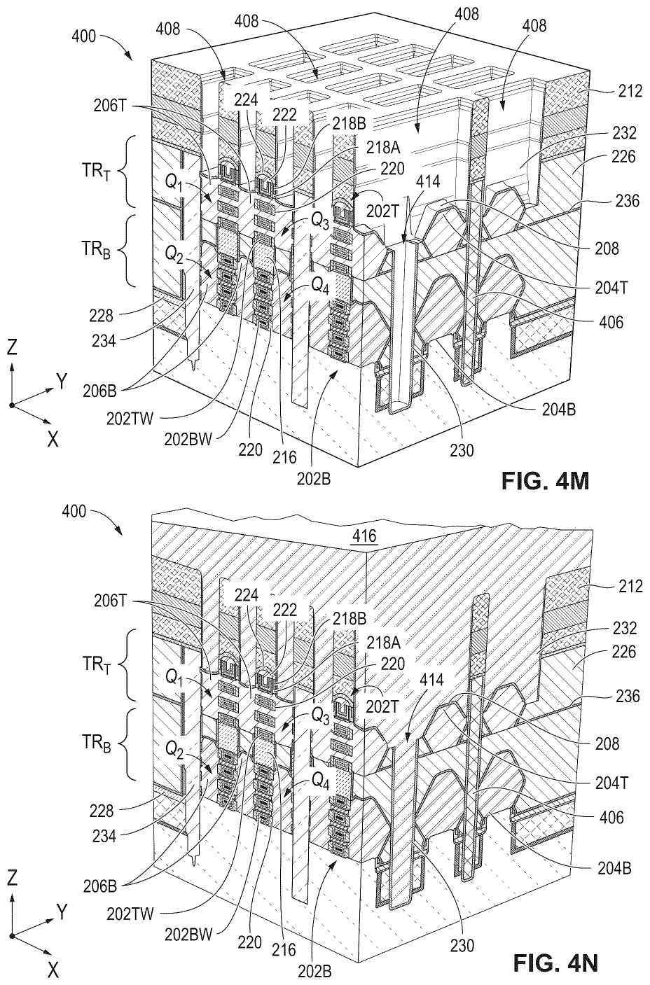

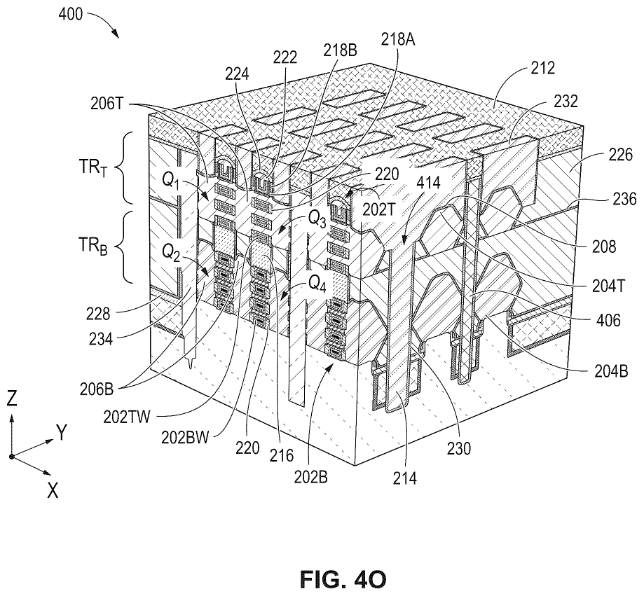

FIGS. 3A and 3B depict a process flow diagram of a method 300 of forming a semiconductor structure 400 that may be the semiconductor structure 200 forming a portion of a complementary field-effect transistor (CFET), according to one or more embodiments of the present disclosure. FIGS. 4A, 4B, 4C, 4D, 4E, 4F, 4G, 4H, 4I, 4J, 4K, 4L, 4M, 4N, and 4O are isometric views of a portion of the semiconductor structure 400 corresponding to various states of the method 300. It should be understood that FIGS. 4A, 4B, 4C, 4D, 4E, 4F, 4G, 4H, 4I, 4J, 4K, 4L, 4M, 4N, and 40 illustrate only partial schematic views of the semiconductor structure 400, and the semiconductor structure 400 may contain any number of transistor sections and additional materials having aspects as illustrated in the figures. It should also be noted that although the method illustrated in FIGS. 3A and 3B is described sequentially, other process sequences that include one or more operations that have been omitted and/or added, and/or has been rearranged in another desirable order, fall within the scope of the embodiments of the disclosure provided herein.

As shown in FIG. 4A, the semiconductor structure 400 includes bottom metal gates 202B and top metal gates 202T extending along the YZ plane, bottom S/D contacts 204B each electrically connected to one end of channel layers (not shown) extending through the bottom metal gates 202B in the X direction via bottom S/D epi regions 206B, and top S/D contacts 204T each electrically connected to one end of channel layers (not shown) extending through the top metal gates 202T in the X direction via top S/D epi regions 206T. A bottom portion of the semiconductor structure 400 including the bottom S/D epi regions 206B forms a bottom field effect transistor (FET) module TRB, and a top portion of the semiconductor structure 400 including the top S/D epi regions 206T forms a top FET module TRT stacked on the bottom FET module TRB in the Z direction.

The bottom metal gates 202B and the top metal gates 202T may be formed of tungsten (W), ruthenium (Ru), molybdenum (Mo), copper (Cu), cobalt (Co), titanium (Ti), nickel (Ni), silver (Ag), gold (Au), iridium (Ir), tantalum (Ta), platinum (Pt), conductive oxides or nitrides thereof, or any combination thereof. The bottom metal gates 202B and the top metal gates 202T may have different work functions to match the electrical characteristics of the bottom FET module TRB and the top FET module TRT. The bottom metal gates 202B are electrically isolated from the top metal gates 202T by middle dielectric isolation (MDI) 216.

The bottom S/D epi regions 206B in the bottom FET module TRB may be formed of epitaxially grown silicon germanium (SiGe), doped with p-type dopants such as boron (B) or gallium (Ga), with a concentration of between about 10²⁰ cm⁻³ and 5×10²¹ cm⁻³, depending upon the desired conductive characteristic of the bottom S/D epi regions 206B. The top S/D epi regions 206T in the top FET module TRT may be formed of epitaxially grown silicon (Si), doped with n-type dopants, such as phosphorus (P), arsenic (As), or antimony (Sb), with a concentration of between about 10²⁰ cm⁻³ and 5×10²¹ cm⁻³, depending upon the desired conductive characteristic of the top S/D epi regions 206T. In some other embodiments, the bottom S/D epi regions 206B in the bottom FET module TRB may be doped with n-type dopants, and the top S/D epi regions 206T in the top FET module TRT may be doped with p-type dopants.

The channel layers (not shown) extending through the top metal gates 202T and the bottom metal gates 202B may be formed of silicon (Si), germanium (Ge), silicon germanium (SiGe), or indium gallium zinc oxide (IGZO).

Surfaces of the bottom metal gates 202B and the top metal gates 202T along the ZX plane are covered by gate spacers 218A and 218B and inner spacers 220 formed of dielectric material, such as silicon oxycarbide (SiOₓC_{y}), silicon carbon nitride (SiCN), silicon carbon oxynitride (SiCON), and silicon nitride (Si₃N₄). The bottom S/D epi regions 206B and the top S/D epi regions 206T are embedded within an inter-layer dielectric (ILD) 226 of formed silicon oxide (SiO₂), silicon oxynitride (SiON), aluminum oxide (Al₂O₃), or any combination thereof. The ILD 226 is protected by shallow trench isolations (STIs) 228. The STIs 228 may be formed of silicon oxide (SiO₂). The semiconductor structure 200 further includes single diffusion breaks (SDBs) 234 to isolate adjacent transistors, and a contact etch stop layer (CESL) 236.

The method 300 begins with block 302, in which a post metal gate chemical mechanical polishing (CMP) process is performed to remove lithography stack used for gap-fill deposition to form the bottom metal gates 202B, the top metal gates 202T, and the MDI 216, and expose the top metal gates 202T, as shown in FIG. 4A.

In block 304, a metal gate cut process is performed to cut the bottom metal gates 202B, the top metal gates 202T, and the ILD 226 in the X direction and form cavities 402 extending along the ZX plane, as shown in FIG. 4B. Cut critical dimension (CD) may vary depending upon the location of the bottom metal gates 202B and the top metal gate 202T and the ILD 226 in a desired physical layout design of the CFET device.

The metal gate cut process may include any appropriate lithography and etch process, using a metal gate cut hardmask 404 deposited on exposed surface of the top metal gates 202T and the ILD 226, performed in a processing chamber, such as the processing chamber 120 shown in FIG. 1.

In block 306, a bottom liner deposition process is performed to deposit a bottom liner 230 on exposed inner surfaces of the cavities 402 and on the metal gate cut hardmask 404, as shown in FIG. 4C. The bottom liner 230 may be formed of silicon nitride (Si₃N₄), silicon carbon nitride (SiCN), silicon carbon oxynitride (SiCON), or any other dielectric material that has etch selectivity to cut metal gate (CMG) isolation gap-fill material 406 used in block 308. The bottom liner 230 may have a thickness of between about 0.5 nm and about 3 nm.

The bottom liner 230 may act as a dielectric liner of the CMG isolation gap-fill material 406 and a self-aligner liner, together with a top liner to be deposited in block 306, for a top-to-bottom interconnect 214 to be formed in block 328.

The bottom liner deposition process may include any appropriate deposition process, such as such as chemical vapor deposition (CVD), physical vapor deposition (PVD), or the like performed in a processing chamber, such as the processing chamber 126, 128, or 130 shown in FIG. 1.

In block 308, a cut metal gate (CMG) isolation gap-fill process is performed to fill the cavities 402 with CMG isolation gap-fill material 406, as shown in FIG. 4D. The CMG isolation gap-fill material 406 may be silicon oxide (SiO₂), silicon oxycarbide (SiOC), silicon carbon oxynitride (SiCON), or any other dielectric material that has etch selectivity from the bottom liner 230 deposited in block 306 and a top liner to be deposited in block 306.

The CMG isolation gap-fill process may include a seam-free gap fill process, such as such as chemical vapor deposition (CVD), physical vapor deposition (PVD), or the like performed in a processing chamber, such as the processing chamber 126, 128, or 130 shown in FIG. 1.

In block 310, a metal gate cut hardmask and CMG isolation gap-fill CMP process is performed to remove the metal gate cut hardmask 404 and overfilled portions of the bottom liner 230 and the CMG isolation gap-fill material 406 over the top metal gates 202T, as shown in FIG. 4E.

This metal gate cut hardmask and CMG isolation gap-fill CMP process also defines height of the top metal gates 202T in Z direction.

In block 312, a top contact trench etch process is performed to form top contact trenches 408 extending along the YZ plane to expose top S/D contacts 204T, as shown in FIG. 4F. The top contact trench etch process may include a metal gate cap selective deposition process to selectively deposit a metal gate cap layer 222 on exposed surfaces of the top metal gates 202T, a metal gate liner deposition process to deposit a metal gate liner 224 on the metal gate cap layer 222, and a lithography and etch process using a top contact etch hardmask 212. The etch process stops at a contact etch stop layer (CESL) 236 formed above the bottom FET module TRB. This top contact trench etch process also defines a height of the ILD 226 in the Z direction to maximize contact resistance and minimize stray capacitance.

The metal gate cap selective deposition process and the metal gate liner deposition process may each include any appropriate deposition process, such as such as chemical vapor deposition (CVD), physical vapor deposition (PVD), or the like performed in a processing chamber, such as the processing chamber 126, 128, or 130 shown in FIG. 1. The etch process may be performed in a processing chamber, such as the processing chamber 120 shown in FIG. 1.

In block 314, a top liner deposition process is performed to deposit a top liner 232 on exposed inner surfaces of the top contact trenches 408, as shown in FIG. 4G. The top liner 232 may be formed of silicon nitride (Si₃N₄), silicon carbon nitride (SiCN), silicon oxycarbonitride (SiOCN), or any other dielectric material that has etch selectivity to the CMG isolation gap-fill material 406 deposited in the CMG isolation gap-fill process in block 308. The top liner 232 may have a thickness of between about 0.5 nm and about 3 nm.

The top liner deposition process may include any appropriate deposition process, such as such as chemical vapor deposition (CVD), physical vapor deposition (PVD), or the like performed in a processing chamber, such as the processing chamber 126, 128, or 130 shown in FIG. 1.

In block 316, a top liner bottom open etch process is performed to remove the top liner 232 from bottoms of the top contact trenches 408 and from the top contact etch hardmask 212, as shown in FIG. 4H.

The top liner bottom open etch process may include any anisotropic etch process, such as a reactive ion etching (RIE) performed in a processing chamber, such as the processing chamber 120 shown in FIG. 1.

In block 318, a source/drain (S/D) silicidation process is performed to form metal silicide 208 on exposed surfaces of the top S/D contacts 204T, as shown in FIG. 4I.

The metal silicide 208 may be titanium silicide (TiSi, TiSi₂), nickel silicide (NiSi, Ni₂Si), molybdenum silicide (MoSi, MoSi₂), cobalt silicide (CoSi₂), tantalum silicide (TaSi₂), or any combination thereof. The metal silicide 208 may lower the resistance of the top S/D contacts 204T.

The S/D silicidation process may include any appropriate deposition process, such as such as chemical vapor deposition (CVD), physical vapor deposition (PVD), or the like performed in a processing chamber, such as the processing chamber 126, 128, or 130 shown in FIG. 1.

In block 320, a carbon bottom layer deposition process is performed to deposit a carbon bottom layer 410 within the top contact trenches 408 and over the top contact etch hardmask 212, as shown in FIG. 4J. The carbon bottom layer 410 may be formed of carbon containing material.

The carbon bottom layer deposition process may include any appropriate gap-fill process, such as a chemical vapor deposition (CVD) process or a spin-on process performed in a processing chamber, such as the processing chamber 126, 128, or 130 shown in FIG. 1.

In block 322, a top-to-bottom via patterning process is performed to form a via 412 through the carbon bottom layer 410, as shown in FIG. 4K.

The top-to-bottom via patterning process may include any appropriate lithography and etch processes, such as photolithography and a reactive ion etching (RIE) performed in a processing chamber, such as the processing chamber 120 shown in FIG. 1.

In block 324, a top-to-bottom via etch process is performed to form a bottom via 414 through the ILD 226 in the bottom FET module TRB, using the patterned carbon bottom layer 410 as a mask, as shown in FIG. 4L.

The via 412 in the carbon bottom layer 410 defines the size of the bottom via 414 to be etched within the CMG isolation gap-fill material 406. If the carbon bottom layer 410 shifts in the Y direction, the bottom via 414 may be bridged to the top S/D contacts 204T without the bottom liner 230. If the carbon bottom layer 410 shifts in the X direction, the bottom via 414 may be bridged to the top metal gates 202T without the top liner 232. The bottom liner 230 and the top liner 232 that are formed of dielectric material that has etch selectivity to the CMG isolation gap-fill material 406 prevent the bottom via 414 from shorting to the top metal gates 202T and to the top S/D contacts 204T. The bottom liner 230 and the top liner 232 act as a self-aligner of the bottom via 414. This lithography overlay margin is determined by thickness of the bottom liner 230 and the top liner 232.

In some other embodiments, this top-to-bottom via etch process is skipped, and a dielectric etch process and a gap-fill process are performed from a backside of the semiconductor structure 400 after a backside power delivery network process in block 332.

The top-to-bottom via etch process may include any appropriate etch process, using the carbon bottom layer 410, performed in a processing chamber, such as the processing chamber 120 shown in FIG. 1.

In block 326, a carbon bottom layer removal process is performed to remove the carbon bottom layer 410, as shown in FIG. 4M. The carbon bottom layer removal process may include any isotropic etch process, such as wet etching, plasma etching, or radical etching, performed in a processing chamber, such as the processing chamber 120 shown in

FIG. 1.

In block 328, a contact metal gap-fill process is performed to fill the bottom via 414 and the top contact trenches 408 with contact metal fill material 416, as shown in FIG. 4N.

The contact metal fill material 416 may be tungsten (W), ruthenium (Ru), molybdenum (Mo), copper (Cu), cobalt (Co), titanium (Ti), nickel (Ni), silver (Ag), gold (Au), iridium (Ir), tantalum (Ta), platinum (Pt), conductive oxides or nitrides thereof, or any combination thereof.

The contact metal gap-fill process may include any appropriate deposition process, such as such as chemical vapor deposition (CVD), physical vapor deposition (PVD), or the like performed in a processing chamber, such as the processing chamber 126, 128, or 130 shown in FIG. 1.

In block 330, a contact CMP process is performed to remove the top contact etch hardmask 212 and form contact plugs 210 and a top-to-bottom interconnect 214 at desired height, as shown in FIG. 4O.

In block 332, a front side back-end-of-line (BEOL) metal interconnect process is performed. The semiconductor structure 400 is then flipped and bonded to a carrier wafer (not shown). A silicon (Si) thinning process is further performed on a backside of the semiconductor structure 400.

In block 334, a backside power delivery network (BSPDN) process is performed to connect the top-to-bottom interconnect 214 to a backside power delivery network (not shown).

The embodiments described herein provide a process integration method to optimize CFET metal routing, leading to improved performance, area reduction, and overall device shrinkage in CFET devices. This process integration method can be also applied to gate-all-around (GAA) FET devices or nanosheet FET devices for top-to-bottom metal routing to implement a backside power distribution network or for double-sided metal routing.

While the foregoing is directed to embodiments of the present disclosure, other and further embodiments of the disclosure may be devised without departing from the basic scope thereof, and the scope thereof is determined by the claims that follow.

1. A semiconductor structure, comprising:
a bottom field effect transistor (FET) module, the bottom FET module comprising:
a bottom metal gate;
a pair of bottom source/drain (S/D) contacts electrically connected to each other through the bottom metal gate in a first direction via bottom S/D epitaxial (epi) regions; and
a top FET module stacked on the bottom FET module in a second direction that is orthogonal to the first direction, the top FET module comprising:
a top metal gate;
a pair of top S/D contacts electrically connected to each other through the top metal gate via top S/D epi regions; and
a top-to-bottom interconnect extending through the bottom FET module and the top FET module in the second direction;
a bottom liner covering surfaces of the top-to-bottom interconnect along a plane parallel to the first direction and the second direction; and
a top liner covering surfaces of the top-to-bottom interconnect along a plane orthogonal to the first direction.

2. The semiconductor structure of claim 1, wherein
the bottom S/D epi regions are epitaxially grown silicon germanium (SiGe) doped with p-type dopants, and
the top S/D epi regions are epitaxially grown silicon (Si) doped with n-type dopants.

3. The semiconductor structure of claim 1, wherein the bottom metal gate and the top metal gate each comprise tungsten (W), ruthenium (Ru), or molybdenum (Mo).

4. The semiconductor structure of claim 1, wherein the top-to-bottom interconnect comprises tungsten (W), cobalt (Co), molybdenum (Mo), or ruthenium (Ru).

5. The semiconductor structure of claim 1, wherein the bottom liner and the top liner each comprise silicon nitride (Si₃N₄), silicon carbon nitride (SiCN), or silicon carbon oxynitride (SiCON).

6. A method of forming a complementary field-effect transistor (CFET), comprising:
exposing a top metal gate, wherein:
the top metal gate is stacked on a bottom metal gate in a first direction, and
the top metal gate and the bottom metal gate are embedded within in an inter-layer dielectric (ILD) and extend along a plane parallel to the first direction and a second direction orthogonal to the first direction;
cutting the top metal gate and the bottom metal gate using a metal gate cut hardmask deposited over the top metal gate and the ILD, and form cavities through the top metal gate, the bottom metal gate, and the ILD;
depositing a bottom liner on exposed inner surfaces of the cavities and on the metal gate cut hardmask;
filling the cavities with cut metal gate (CMG) isolation gap-fill material;
removing the metal gate cut hardmask and overfilled portions of the bottom liner and the CMG isolation gap-fill material over the top metal gate;
forming a top contact trench extending along the plane parallel to the first direction and the second direction, using a top contact etch hardmask, and expose a pair of top source/drain (S/D) contacts that are electrically connected to each other through the top metal gate;
depositing a top liner on exposed inner surfaces of the top contact trench;
removing the top liner from a bottom of the top contact trench and from the top contact etch hardmask;
forming metal silicide on exposed surfaces of the top S/D contacts;
depositing a carbon bottom layer within the top contact trench and over the top contact etch hardmask;
forming a via through the carbon bottom layer;
forming a bottom via through the ILD using the patterned carbon bottom layer;
removing the carbon bottom layer;
filling the bottom via and the top contact trench with contact metal fill material; and
removing the top contact etch hardmask and form a contact plug and a top-to-bottom interconnect.

7. The method of claim 6, wherein the bottom metal gate and the top metal gate each comprise tungsten (W), ruthenium (Ru), or molybdenum (Mo).

8. The method of claim 6, wherein the contact metal fill material comprises tungsten (W), cobalt (Co), molybdenum (Mo), or ruthenium (Ru).

9. The method of claim 6, wherein the bottom liner and the top liner each comprise silicon nitride (Si₃N₄), silicon carbon nitride (SiCN), or silicon carbon oxynitride (SiCON).

10. The method of claim 6, wherein the CMG isolation gap-fill material comprises silicon oxide (SiO₂), silicon oxycarbide (SiOC), or silicon carbon oxynitride (SiCON).

11. The method of claim 6, wherein the carbon bottom layer comprises carbon.

12. The method of claim 6, wherein the forming of the bottom via comprises self-alignment of the bottom via by the bottom liner and the top liner.

13. The method of claim 6, wherein:
the removing of the top liner comprises an anisotropic etch process, and the filling of the cavities comprises a seam-free gap fill process.

14. A method of forming a complementary field-effect transistor (CFET), comprising:
cutting a top metal gate and a bottom metal gate embedded in an inter-layer dielectric (ILD) using a metal gate cut hardmask deposited over the top metal gate and the ILD, and form cavities through the top metal gate, the bottom metal gate, and the ILD, wherein:
the top metal gate is stacked on the bottom metal gate in a first direction,
the top metal gate and the bottom metal gate extend along a plane parallel to the first direction and a second direction orthogonal to the first direction, and
the cavities extend along a plane orthogonal to the second direction;
depositing a bottom liner on exposed inner surfaces of the cavities and on the metal gate cut hardmask;
filling the cavities with cut metal gate (CMG) isolation gap-fill material;
removing the metal gate cut hardmask and overfilled portions of the bottom liner and the CMG isolation gap-fill material over the top metal gate;
forming a top contact trench extending along the plane parallel to the first direction and the second direction, using a top contact etch hardmask, and expose a pair of top source/drain (S/D) contacts that are electrically connected to each other through the top metal gate;
depositing a top liner on exposed inner surfaces of the top contact trench;
removing the top liner from a bottom of the top contact trench and from the top contact etch hardmask;
forming metal silicide on exposed surfaces of the top S/D contacts;
depositing a carbon bottom layer within the top contact trench and over the top contact etch hardmask;
forming a via through the carbon bottom layer;
forming a bottom via through the ILD using the patterned carbon bottom layer;
removing the carbon bottom layer; and
filling the bottom via and the top contact trench with contact metal fill material.

15. The method of claim 14, wherein the bottom metal gate and the top metal gate each comprise tungsten (W), ruthenium (Ru), or molybdenum (Mo).

16. The method of claim 14, wherein the contact metal fill material comprises tungsten (W), cobalt (Co), molybdenum (Mo), or ruthenium (Ru).

17. The method of claim 14, wherein:
the bottom liner and the top liner each comprise silicon nitride (Si₃N₄), silicon carbon nitride (SiCN), or silicon carbon oxynitride (SiCON), and
the CMG isolation gap-fill material comprises silicon oxide (SiO₂), silicon oxycarbide (SiOC), or silicon carbon oxynitride (SiCON).

18. The method of claim 14, wherein the carbon bottom layer comprises carbon.

19. The method of claim 14, wherein the forming of the bottom via comprises self-alignment of the bottom via by the bottom liner and the top liner.

20. The method of claim 14, wherein:
the removing of the top liner comprises an anisotropic etch process, and
the filling of the cavities comprises a seam-free gap fill process.
